(19) United States
(12) Patent Application Publication
(10) Pub. No.: US 2012/0199989 A1
(43) Pub. Date: Aug. 9, 2012

(54) CIRCUIT ARRANGEMENT AND MANUFACTURING METHOD THEREOF

(75) Inventors: Nicola Schulz, Turgi (CH); Samuel Hartmann, Dottikon (CH)

(73) Assignee: ABB Technology AG, Zurich (CH)

(21) Appl. No.: 13/431,457

(22) Filed: Mar. 27, 2012

Related U.S. Application Data
(63) Continuation of application No. PCT/EP2010/064377, filed on Sep. 28, 2010.

(30) Foreign Application Priority Data
Sep. 28, 2009 (EP) 09171447.7

(51) Int. Cl. H01L 23/48; H01L 21/50

(52) U.S. Cl. 257/782; 438/118; 257/E23.001; 257/E21.499

(57) ABSTRACT

Exemplary embodiments of the disclosure are directed to a circuit arrangement in which a power functional device and a conductor element are mounted and a method of manufacturing the same. The arrangement includes a substrate, a wiring layer provided on the substrate and electrically connected to the functional device and to the conductor element and an intermediate electric contact device. The intermediate electric contact device is mounted on the wiring layer to provide on the side opposite to the wiring layer a contact region for contacting the conductor element. The conductor element is contacting the intermediate electric contact device in the contact region which is opposite to an area, in which the electric contact device is fixed to the wiring layer.

### RELATED APPLICATION(S)

This application claims priority as a continuation application under 35 U.S.C. §120 to PCT/EP2010/064377, which was filed as an International Application on Sep. 28, 2010 designating the U.S., and which claims priority to European Patent Application No. 09171447.7 filed in Europe on Sep. 28, 2009, the entire contents of which are hereby incorporated by reference in their entireties.

### FIELD

The disclosure relates to a semiconductor mount, such as a circuit arrangement in which a power functional device, such as a transistor or diode, and a conductor element are mounted.

### BACKGROUND INFORMATION

Document EP 1 711 040 B1 describes a circuit device in which a functional device and an externally leading conductor are mounted, the circuit device including a substrate, a wiring layer provided on the substrate and electrically connected to the functional device and to the externally leading conductor, and an additional coating metal layer formed on a part of the wiring layer to provide a corresponding contact region for contacting the functional device. The wiring layer and the additional coating metal layer constitute a metallization of the substrate. Low temperature bonding specifies silver plating which can hinder the use of ultra sonic welding for the terminals.

The metallization constituted by the wiring layer and the coating metal layer on the part of the wiring layer contributes with relatively high resistivity contribution (about 30μΩ) to the overall arrangement resistance. One possible solution is using a substrate metallization that is in general thicker for decreasing the resistivity. A problem when increasing the metallization thickness is that the layout tolerances increase at the same time. Therefore, the layout would have to be changed with loss of cross sectional area again.

Another drawback of a generally thicker substrate metallization is that the mechanical stresses at the metallization edges of the wiring layer will increase where crack growth in the ceramic substrate is initiated (the polyimide might prevent it).

From EP 1 830 406 A1 a power module is known, which includes a power semiconductor mounted on top of a heat spreader. As shown in the figures of EP 1 830 406 A1 the heat spreader is aligned with the element on which it is mounted.

From DE 43 00 516 A1 another power module is known. In this known power module, a contact plate is arranged on top of a diode in order to ease the connection to a massive copper element.

From “Low-inductance module construction for high speed, high-current IGBT module suitable for electric vehicle application” by T. Tsunoda et al. (Power Semiconductor devices and ICS, 1993, ISPSD '93., Proceedings of the 5th International Symposium on Monterey, Calif., USA 18-20 May 1993, New York, N.Y., USA IEEE, US, 18 May 1993) a multi-layered DBC substrate is known. By the proposed construction, the collector and emitter terminals are arranged closely to each other in order to compensate for the magnetic field generated by the current flow in individual terminals.

### SUMMARY

An exemplary circuit arrangement is disclosed comprising: a substrate; a wiring layer provided on the substrate and electrically connected to a power functional device and to a conductor element; and an intermediate contact device, which is mounted on the wiring layer to provide a contact region for contacting the conductor element on a side opposite to the wiring layer, wherein the intermediate contact device has at least a first side and a second side, the second side is at least substantially parallel to the first side, wherein the intermediate contact device is fixed to the wiring layer on the first side, wherein the conductor element is contacting the intermediate contact device on the second side in the contact region

An exemplary method of manufacturing a circuit arrangement is disclosed, in which at least one power functional device and at least one conductor element is mounted, wherein the arrangement includes a substrate and a wiring layer provided on the substrate, the method comprising the steps of: mounting and electrically contacting an intermediate contact device on the wiring layer to provide a contact region on one side of the intermediate contact device, which is opposite to the wiring layer; and directly electrically connecting the conductor element to the intermediate contact device in the contact region.

### BRIEF DESCRIPTION OF THE DRAWINGS

These and other aspects of the disclosure will be apparent from and elucidated with reference to the embodiments described hereinafter.

In the drawings:

FIG. 1 depicts a first circuit arrangement in accordance with an exemplary embodiment of the present disclosure;

FIG. 2 shows a sectional view of the first circuit arrangement in accordance with an exemplary embodiment of the present disclosure;

FIG. 3 shows a circuit arrangement in accordance with an exemplary embodiment of the present disclosure;

FIG. 4 shows a sectional view of a third circuit arrangement in accordance with an exemplary embodiment of the present disclosure; and

FIG. 5 shows a fourth circuit arrangement in accordance with an exemplary embodiment of the present disclosure.

### DETAILED DESCRIPTION

Exemplary embodiments of the present disclosure provide a circuit arrangement, which overcomes the aforementioned disadvantages.

An exemplary intermediate electric contact device is fixed to the according part of the wiring layer only in finite sub-areas of the entire outer side (or interface) of the wiring layer. The intermediate contact device has a first side on which the intermediate contact device is fixed to the wiring layer. Opposite to the part of the wiring layer, in which the intermediate contact device is fixed to the wiring layer, the intermediate contact device has a contact region, in which the conductor element is contacting the intermediate contact device. By this arrangement, the wiring layer as well as the substrate can be protected from damages during attaching of the conductor element.

An advantage provided by the exemplary embodiments described herein can include when fixing the intermediate contact device on top of a track of the wiring layer which is thinner than the intermediate contact device, the stress at the metallization edge at the wiring layer is not increased much because a fixation area of the fixation is smaller than the metallization area below. There is a margin between the intermediate contact device and the metallization edge.

According to an exemplary embodiment of the present disclosure, the intermediate contact device is fixed to the wiring layer by soldering and/or low-temperature bonding (LTB).

According to another exemplary embodiment of the present disclosure, the conductor element is an externally leading conductor.

According to yet another exemplary embodiment of the present disclosure, the power functional device is a power transistor, such as an insulated gate bipolar transistor, or a (power) diode. The insulated gate bipolar transistor or IGBT is a three-terminal power semiconductor device, noted for high efficiency and fast switching. In the active state of the IGBT, a voltage or potential difference between the emitter as well as a corresponding emitter track and the gate as well as the corresponding gate track of the IGBT is a low voltage. Furthermore, selectively thickening the emitter tracks is less critical for reliability because the emitter track does not see higher temperatures than the collector tracks.

According to one exemplary embodiment of present disclosure, the at least partial electrically conductible contact device is a metal foil or metal plate. The metal plate can be standard insulated metal technology (IMS). The bonding of the plate can be done in the process step as the bonding of the power functional device (die-bonding). The metal foil or metal plate can be thicker than 100 μm or 200 μm, for example.

According to another exemplary embodiment of the present disclosure, the at least partial electrically conductible contact device is a circuit board for selectively contacting other elements and/or devices of the circuit arrangement.

According to yet another exemplary embodiment of the present disclosure, the intermediate contact device and at least one bonding element for electrically contacting the power functional device with the wiring layer are integrally formed. The intermediate contact device being integrally formed with the bonding element saves costs and simplifies the mounting of the arrangement.

Exemplary embodiments of the present disclosure further relate to a method of manufacturing a circuit arrangement in which at least one functional device and at least one conductor element is mounted, wherein the arrangement includes (e.g., comprises) a substrate and a wiring layer provided on the substrate, the method including the steps of mounting and electrically contacting an intermediate contact device on an the wiring layer to provide contact region on one side of the intermediate contact device, which is opposite to the wiring layer (14), and directly electrically connecting the conductor element to the intermediate contact device in the contact region.

According to an exemplary embodiment of the present disclosure, the intermediate contact device is fixed to the wiring layer by soldering and/or low-temperature bonding (LTB).

According to another exemplary embodiment of the present disclosure, the wiring device is an externally leading conductor or terminal of the arrangement.

According to yet another exemplary embodiment of the present disclosure, the power functional device is a power transistor, such as an insulated gate bipolar transistor, or diode.

According to one exemplary embodiment of the present disclosure, the at least partial electrically conductible contact device is a metal foil or metal plate. The metal plate can be standard IMS technology. The bonding of the plate can be done in the process step as the bonding of the power functional device (die-bonding). The metal foil or metal plate can be thicker than 100 μm or 200 μm, for example.

According to another exemplary embodiment of the present disclosure, the at least partial electrically conductible contact device is a circuit board.

According to yet another exemplary embodiment of the present disclosure, the intermediate contact device and at least one bonding element for electrically contacting the power functional device with the wiring layer are integrally formed. The intermediate contact device being integrally formed with the bonding element saves costs and simplifies the mounting of the arrangement.

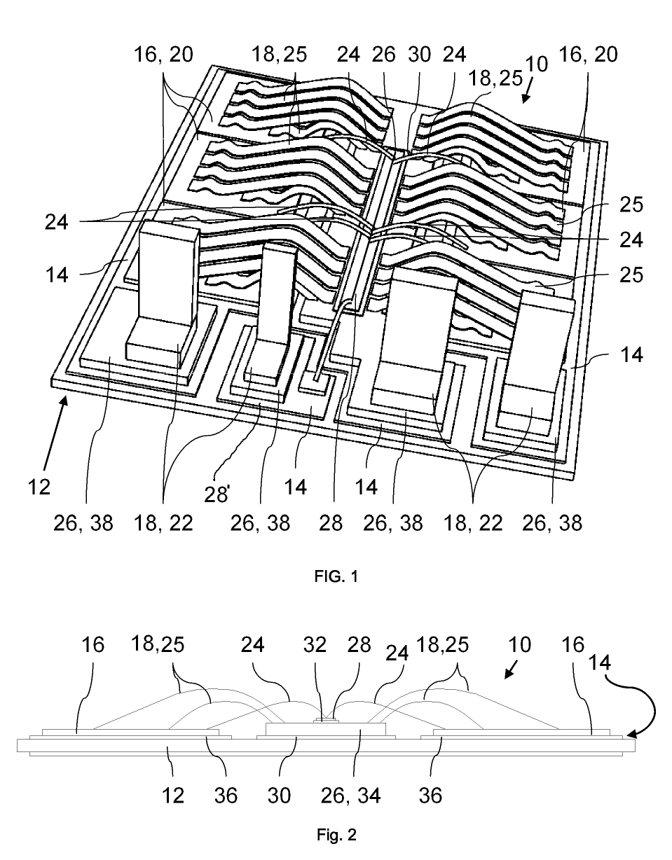

FIG. 1 depicts a first circuit arrangement in accordance with an exemplary embodiment of the present disclosure; and FIG. 2 shows a sectional view of the first circuit arrangement in accordance with an exemplary embodiment of the present disclosure.

Together FIGS. 1 and 2 show a power circuit arrangement 10 including a substrate 12 being a ceramic substrate and a structured wiring layer 14 provided on the substrate 12. The wiring layer 14 has at least a first track and a second track, which is insulated from the first track. In an exemplary embodiment, the first track can be formed by a collector track 36 and the second track can be formed by an emitter track 30. The wiring layer could also be formed to have more than two tracks as desired. The wiring layer 14 can have a third track formed as a gate track. The structured wiring layer 14 can be made of copper. The wiring layer 14 can have a thickness of 200 μm to 400 μm. In the exemplary circuit arrangement 10 of the present embodiment, six power functional devices 16 (not shown in detail), and a plurality of conductor elements 18 are mounted on the power circuit arrangement 10. The power functional devices 16 are power semiconductor devices such as power transistors 20, for example, power IGBTs (IGBT: Insulated Gate Bipolar Transistor), and diodes. The conductor elements 18 can include externally leading conductors 22 for externally connecting the power functional device 16 outside the circuit arrangement 10 and/or bonding elements, in particular bonding wires 25. The externally leading conductors 22 can include L-shaped power terminals of the circuit arrangement. These power terminals can be formed of so called “moly plates”, such as a metal-free compound composed of molybdenum disulfide and graphite, which can include a synthetic non-melting carrier.

As shown in FIG. 1, the power circuit arrangement 10 has four externally leading conductors 22. Between each of the externally leading conductor 22 and the respective area of the wiring layer 14 just below the externally leading conductor 22 an intermediate contact device 26 is arranged. The intermediate contact device 26 has a first side and a second side which is at least approximately parallel to the first side. The first side of the intermediate contact device 26 is electrical conductively fixed to the wiring layer 14. On the second side, the intermediate contact device 26 provides a contact region for contacting at least one conductor element 18, for example the externally leading conductor 22. The conductor element 18 is electrical conductively fixed on the intermediate contact device 26. Further, the contact region is opposite of the area on the first side in which the intermediate contact device is electrical conductively fixed to the wiring layer 14.

The intermediate contact devices 26 between the conductor elements 18, e.g. the externally leading conductors (terminals) 22, and the wiring layer 14 protect the ceramic substrate 12 when bonding the externally leading conductors 22 by ultrasonic welding (also laser and resistive welding). For that purpose the intermediate contact devices 26 should also be bonded on top of the parts of the structured wiring layer 14 being the collector tracks 36, emitter track 30 and/or the gate track 28′ just below the feet of the externally leading conductors 22 (terminal feet). It should be understood, that the intermediate contact device 26 should be used if connecting the conductor element 18 directly to the wiring layer 14 could damage the ceramic substrate 12 and/or the wiring layer 14. Thus in other exemplary embodiments one or several of the conductor elements 18, in particular one or several of the externally leading conductors 22 can be connected to the respective track of the wiring layer by an intermediate contact device 26.

The intermediate contact device can be formed of a metal foil or metal plate. Hence, the intermediate contact device 26 is self-contained. The bonding of the metal foil or metal plate can be done in the process step as the bonding of the power functional device (die-bonding). The metal foil or metal plate can be thicker than 100 μm or 200 μm, for example.

In general, the power functional devices 16 can be electrically connected to the externally leading conductors 22 via their connector areas (not shown), bonding elements being bonding wires 25 and the intermediate contact devices 26 as well as tracks 36 established by the wiring layer 14 and intermediate contact devices 26.

In the exemplary embodiment shown in FIGS. 1 and 2, an upper or emitter contact of each of the power functional devices 16 is electrically contacted by bonding wires 25 leading to a metal foil 34 arranged on the emitter track 30 of the wiring layer 14. The metal foil 34 can be an exemplary embodiment of the intermediate contact device 26 according to the present disclosure. A lower or collector contact of each of the power functional devices 16 is in electrical contact to one of the collector tracks 36 of the wiring layer 14. Further, on each collector track 36 a metal plate 38 is arranged, which is a further embodiment of the intermediate contact device 26. As described above, the metal plate 38 on the collector tracks 36 is for protecting the ceramic substrate 12. The metal foil 34 on the emitter track 30 is not only for protecting the ceramic substrate 12 but also for lowering the resistivity as discussed below.

The intermediate contact devices 26 can be arranged in direct electrical contact to the conductor elements 18 (for example the externally leading conductors 22) and/or to the wiring layer, which can be formed by the at least first and second track, in particular the collector track 36 and the emitter track 30 for the IGBT transistors 20.

An additional electrical resistance film 32 is located between the gate track 28 formed by an additional wiring strip and the emitter track 30 formed by the respective part of the structured wiring layer 14 and the intermediate contact device 26 being a metal foil 34. The metal foil 34 is electrical conductively fixed on the respective part of the structured wiring layer 14. The gate track 28 and the intermediate contact device, on which the gate track 28 is provided, can be formed by a partial electrically conductible metal foil or metal plate by insulated metal technology (IMS).

Each of the two collector tracks shown in FIGS. 1 to 5 directly contacts three IGBTs and/or diodes by their collector connector areas.

According to an exemplary embodiment of the present disclosure, the intermediate electric contact devices 26 are mounted on a respective part of the wiring layer 14 to provide a corresponding contact region for contacting the power functional device 16. Further, an intermediate electric contact device 26 is mounted on one part of the wiring layer 14 that forms the emitter track 30.

As shown in more detail in FIG. 2, in the circuit arrangement 10 can be a metallic plate or thick metallic foil 34 is bonded on the part of the wiring layer 14 building the emitter track 30. The plate or foil 34 provides on top the additional metallization or wiring strip being the gate track 28 for the IGBTs. The plate or foil can be standard IMS technology (“DENKA HITT PLATE”). The bonding of the plate or foil 34 can be done in the process step as the bonding of the power functional devices 16 (being a die-bonding). The bonding method can include soldering or low-temperature bonding (LTB). Thus, the joint between the wiring layer 14 and the intermediate contact device 26 is a soldering joint or a joint made by low-temperature bonding. The plate on top of the part of the wiring layer 14 lowers the resistance of the overall emitter path. For a standard IGBT module (e.g. “HiPak2”) the reduction could be more than 10μΩ. For a 1700 V/3600 A arrangement or module, this reduces the voltage drop by more than 36 mV (around 1.5% of the on-stat voltage).

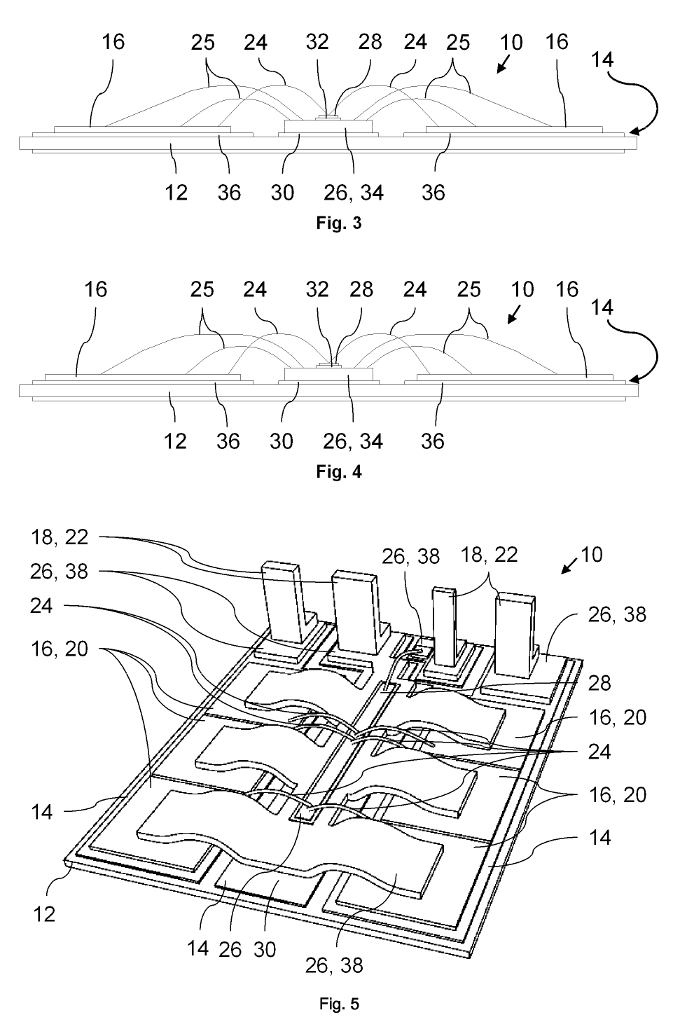

The gained thickness of the emitter track 30 allows making the emitter track 30 narrower. The narrower emitter track 30 allows to reduce the overall area of the substrate 12 or to form a larger area of the collector tracks 36. A corresponding arrangement is shown in FIG. 3.

FIG. 3 shows a circuit arrangement in accordance with an exemplary embodiment of the present disclosure. FIG. 3 is a variant of the embodiment shown in FIG. 2, wherein the width of the emitter track 30 is narrower than in the embodiment of the circuit arrangement 10 shown in FIG. 2. The larger area of the collector track 36 increases the heat spreading. Having a larger distance between the surface of the substrate 12 and the heating power functional device 16 will also improve the case temperature cycling capability because there is less temperature difference ΔT and thus less stress at the surface of the substrate solder.

Because of the narrower emitter track 30, larger collector tracks 36 can be used with a substrate 12 of the same size. FIG. 4 shows a sectional view of a third circuit arrangement in accordance with an exemplary embodiment of the present disclosure. FIG. 4 shows an according circuit arrangement with larger collector tracks. The active area of the collector tracks can be increased by more than 10%.

FIG. 5 shows a fourth circuit arrangement in accordance with an exemplary embodiment of the present disclosure. FIG. 5 is a variant of the exemplary embodiments shown in FIGS. 1 to 4, wherein a plurality of bonding metal sheets 38 electrically connecting the emitter track 30 to the corresponding emitter connector areas of the power functional devices 16 and the intermediate contact device 26 connecting the emitter track 30 with the corresponding (emitter) conductor element 18 being an externally leading conductor 22 are integrally formed as a intermediate contact device 26 fixed to the emitter connector area of the power functional devices 16 and to the corresponding (emitter) conductor element 18. This intermediate contact device 26 shown in FIG. 5 is directly contacting the emitter of the power functional device 16 and/or the corresponding conductor element 18.

In the die-attach process intermediate contact devices 26, such as metal plates 38, can be bonded that provide several functions. Lowering the electric resistance, protection of the ceramics when welding the power terminals (e.g. strong moly plates), and carrying the gate circuit on top.

The corresponding exemplary manufacturing method includes the steps of fixing the intermediate contact device, e.g. the metal foil 34 or plate 38, on an according part of the wiring layer 14 only in finite sub-areas of the entire outer side of the wiring layer to provide a corresponding contact region for the conductor element 18, and directly or indirectly electrically connecting the functional device(s) and the conductor 22 to the metal foil 34 or plate 38.

The corresponding resistance of the collector tracks drops from 8.2μΩ in to 6.8μΩ, the resistance of the emitter track drops from 24.2μΩ in to 6.8μΩ, the total reduction is about 18.8μΩ.

In further exemplary embodiments, only one or several of the intermediate contact devices shown in FIGS. 1 to 5 can be arranged on the wiring layer 14. It is also possible that at least one conductor element 18 can be directly connected to the wiring layer 14.

While the disclosure has been illustrated and described in detail in the drawings and foregoing description, such illustration and description are to be considered illustrative or exemplary and not restrictive; the disclosure is not limited to the disclosed embodiments.

Other variations to be disclosed embodiments can be understood and effected by those skilled in the art in practicing the claimed disclosure, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting scope.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### REFERENCE SIGNS LIST

10 circuit arrangement
12 substrate
14 wiring layer
16 functional device
18 conductor element
20 power transistor
22 externally leading conductor
24 bonding wire
25 bonding metal sheet
26 intermediate contact device
28 gate track
30 emitter track
32 resistance film
34 metal foil
26 collector track
38 metal plate

What is claimed is:

1. A circuit arrangement comprising:
a substrate;
a wiring layer provided on the substrate and electrically connected to a power functional device and to a conductor element; and
an intermediate contact device, which is mounted on the wiring layer to provide a contact region for contacting the conductor element on a side opposite to the wiring layer,
wherein the intermediate contact device has at least a first side and a second side, the second side is at least substantially parallel to the first side, wherein the intermediate contact device is fixed to the wiring layer on the first side, wherein the conductor element is contacting the intermediate contact device on the second side in the contact region.

2. The circuit arrangement according to claim 1, wherein the intermediate contact device is fixed to the wiring layer by at least one of a soldering joint and by a joint made by low-temperature bonding.

3. The circuit arrangement according to claim 1, wherein the intermediate electric contact device is fixed to a part of the wiring layer in finite sub areas of an entire outer side of the wiring layer.

4. The circuit arrangement according to claim 1, wherein the conductor element is an externally leading conductor or a bonding element leading from the intermediate contact device to the power functional device.

5. The circuit arrangement according to one of claim 1, wherein the power functional device is a power semiconductor device.

6. The circuit arrangement according to claim 1, wherein the intermediate contact device is at least partially electrically conductible, and wherein the intermediate contact device is one of a metal foil, a metal sheet or a metal plate.

7. The circuit arrangement according to claim 1, wherein the at least partially electrically conductible intermediate contact device is a circuit board.

8. The circuit arrangement according to claim 1, wherein the intermediate contact device is thicker than 100 μm.

9. The circuit arrangement according to claim 1, wherein the intermediate contact device and a bonding element for electrically contacting the power functional device with the wiring layer are integrally formed.

10. The circuit arrangement according to claim 1, wherein the intermediate contact device is in direct electrical and mechanical contact to the wiring layer.

11. The circuit arrangement according to claim 1, wherein the intermediate contact device is self-contained.

12. The circuit arrangement according to claim 1, wherein the contact region is opposite to an area on the first side in which the intermediate contact device is electrically conductively fixed to the wiring layer.

13. The circuit arrangement according to claim 15, wherein the power semiconductor device is a power transistor including one of an insulated gate bipolar transistor and a diode.

14. A method of manufacturing a circuit arrangement, according to claim 1, in which at least one power functional device and at least one conductor element is mounted, wherein the arrangement includes a substrate and a wiring layer provided on the substrate, the method comprising the steps of:
mounting and electrically contacting an intermediate contact device on the wiring layer to provide a contact region on one side of the intermediate contact device, which is opposite to the wiring layer; and
directly electrically connecting the conductor element to the intermediate contact device in the contact region.

15. The method according to claim 14, wherein mounting the intermediate contact element to a part of the wiring layer includes fixing the intermediate contact element to the part only in finite sub-areas of the entire outer side of the wiring layer.

16. The method according to claim 14, wherein the intermediate contact device is fixed to the wiring layer by soldering and/or low-temperature bonding.

17. The method according to claim 14, wherein the conductor element is an externally leading conductor.

18. The method according to claim 14, wherein the power functional device is a power semiconductor.

19. The method according to claim 14, wherein the intermediate contact device is at least partial electrically conductible, and wherein the intermediate contact device is one of a metal foil, a metal sheet or a metal plate.

20. The method according to claim 14, wherein the intermediate contact device is at least partially electrically conductible, and wherein the intermediate contact device is a circuit board.

21. The method according to claim 12, wherein the intermediate contact device and a bonding element for electrically contacting the power functional device with the wiring layer are integrally formed.

22. The method according to claim 18, wherein the power semiconductor is a power transistor including one of an insulated gate bipolar transistor and a diode.
